(19) United States
(12) Patent Application Publication
(10) Pub. No.: US 2009/0229757 A1
(43) Pub. Date: Sep. 17, 2009

(54) PLASMA PROCESSING APPARATUS

(75) Inventor: Shinji Muto, Nishinomiya-shi (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/401,864

(22) Filed: Mar. 11, 2009

(30) Foreign Application Priority Data
Mar. 11, 2008 (JP) 2008-061132

(51) Int. Cl. H01L 21/3065; C23F 1/08

(52) U.S. Cl. 156/345.48

(57) ABSTRACT

The plasma processing apparatus includes: a chamber including an upper electrode and a lower electrode; a matching box electrically connected to the lower electrode, wherein the matching box is freely attached and detached with respect to the lower electrode and supplies a radio frequency (RF) power to the lower electrode; and an air cylinder fixed at the chamber and pulling up the matching box to a position where the matching box is connected to the lower electrode. The lower electrode and the matching box are electrically connected to each other via a cylindrical female terminal connected to one of the lower electrode and the matching box and a male terminal connected to other one of the lower electrode and the matching box and inserted in an inner diameter surface of the female terminal, and at least one of the female terminal and the male terminal includes an elastic conductor covering a contact surface that contacts other one of the female terminal and the male terminal.

### CROSS-REFERENCE TO RELATED PATENT APPLICATIONS

This application claims the benefit of Japanese Patent Application No. 2008-061132, filed on Mar. 11, 2008, in the Japan Patent Office, the disclosure of which is incorporated herein in its entirety by reference.

### BACKGROUND OF THE INVENTION

1. Field of the Invention

The present invention relates to a plasma processing apparatus.

2. Description of the Related Art

A conventional plasma processing apparatus is disclosed, for example, in Japanese Laid-open Patent Publication No. 2002-184761. The conventional plasma processing apparatus disclosed in this publication includes a chamber in which a wafer is plasma processed, a matching box for supplying a radio frequency (RF) voltage to the chamber, and an elevation driving unit which elevates the matching box. In addition, terminals of the chamber and the matching box can be connected to each other for electrically connecting the chamber to the matching box.

In the plasma processing apparatus having the above structure, a gap between the terminals to be connected to each other needs to be reduced so as to guarantee an electrical connection. In this case, a resistance that occurs when the terminals are connected to each other increases. Thus, a large force is required for connecting the terminals. Thus, the plasma display apparatus disclosed in the above publication includes the elevation driving unit, which includes a ball screw, a guide rail, a rail, an operating handle, and an endless belt.

However, the elevation driving unit has a large and complicated structure. In addition, when the gap between the terminals is reduced, a contact portion may be damaged when connecting the terminals.

### SUMMARY OF THE INVENTION

To solve the above and/or other problems, the present invention provides a plasma processing apparatus which includes a small-sized elevation driving unit for a matching box so that an electrical connection between a chamber and the matching box can be guaranteed.

According to an aspect of the present invention, there is provided a plasma processing apparatus including: an upper electrode and a lower electrode facing each other; a process container in which a substrate supported by the lower electrode is plasma processed; a matching box electrically connected to the lower electrode, wherein the matching box may be freely attached and detached with respect to the lower electrode and supplies a radio frequency (RF) power to the lower electrode; and a fluid pressure cylinder fixed at the process container and pulling up the matching box to a position where the matching box is connected to the lower electrode. The lower electrode and the matching box may be electrically connected to each other via a female terminal connected to one of the lower electrode and the matching box and a male terminal connected to other one of the lower electrode and the matching box and inserted in the female terminal, and at least one of the female terminal and the male terminal may include an elastic conductor covering a contact surface which contacts other one of the female terminal and the male terminal.

In the above structure, the female terminal and the male terminal are covered with the elastic conductor so that a predetermined gap between the male terminal and the female terminal can be formed. As such, a resistance that occurs when the female terminal and the male terminal are connected to each other can be reduced, and the female terminal and the male terminal can be prevented from being damaged during connection. In addition, due to a reduction in the resistance that occurs when the female terminal and the male terminal are connected to each other, a small-sized air cylinder can be used as an elevation driving unit for driving the matching box.

The elastic conductor may be a cylindrical member having a wrinkled hose structure. The wrinkled hose structure is elastically deformed, a mountain portion thereof contacts an inner diameter surface of the female terminal, and a valley portion thereof contacts an outer diameter surface of the male terminal so that, even though a predetermined gap between the male terminal and the female terminal is formed, the male terminal and the female terminal can be electrically connected to each other.

The fluid pressure cylinder may be disposed perpendicularly above the center of gravity of the matching box. As such, the matching box can be pulled up in a horizontal direction so that the male terminal and the female terminal can be properly electrically connected to each other.

The fluid pressure cylinder may be an air cylinder using air pressure. Also, a hydraulic cylinder using hydraulic pressure may be used.

The fluid pressure cylinder may be a double acting cylinder. Also, a single acting cylinder elastically supporting a piston toward one side may be used.

### BRIEF DESCRIPTION OF THE DRAWINGS

The above and other features and advantages of the present invention will become more apparent by describing in detail exemplary embodiments thereof with reference to the attached drawings in which:

FIG. 1 is a longitudinal cross-sectional view of a plasma processing apparatus according to an embodiment of the present invention;

FIG. 2 is a plan view schematically illustrating the plasma processing apparatus of FIG. 1;

FIG. 3 is an expanded view illustrating a state where the lower electrode and the matching box are not connected to each other;

FIG. 4 is an expanded view illustrating a state where the lower electrode and the matching box are connected to each other; and

FIG. 5 illustrates a fluid pressure cylinder according to another embodiment of the present invention.

### DETAILED DESCRIPTION OF THE INVENTION

The attached drawings for illustrating exemplary embodiments of the present invention are referred to in order to gain a sufficient understanding of the present invention, the merits thereof, and the objectives accomplished by the implementation of the present invention. Hereinafter, the present invention will be described in detail by explaining exemplary embodiments of the invention with reference to the attached drawings. Like reference numerals in the drawings denote like elements.

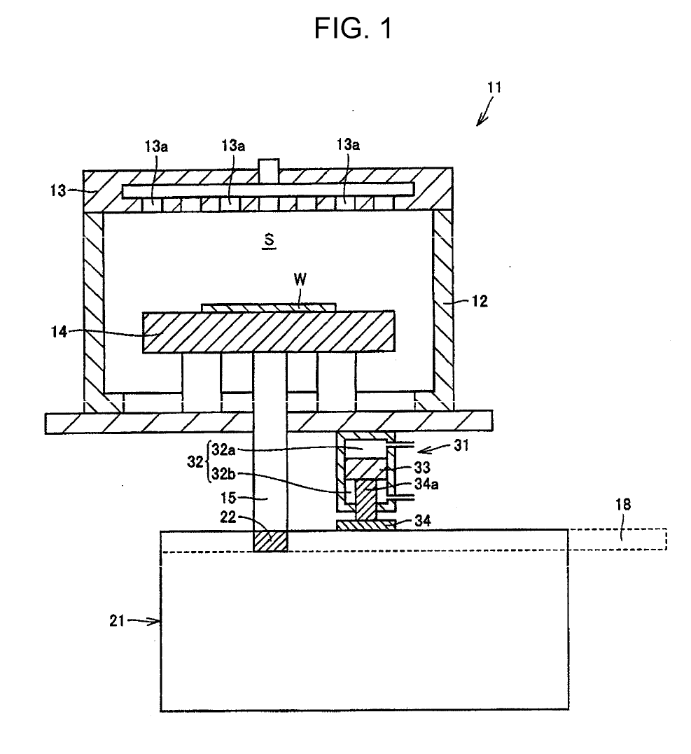

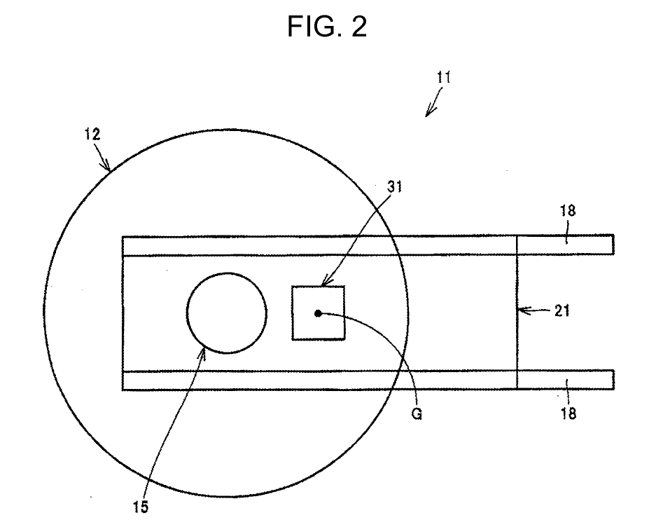

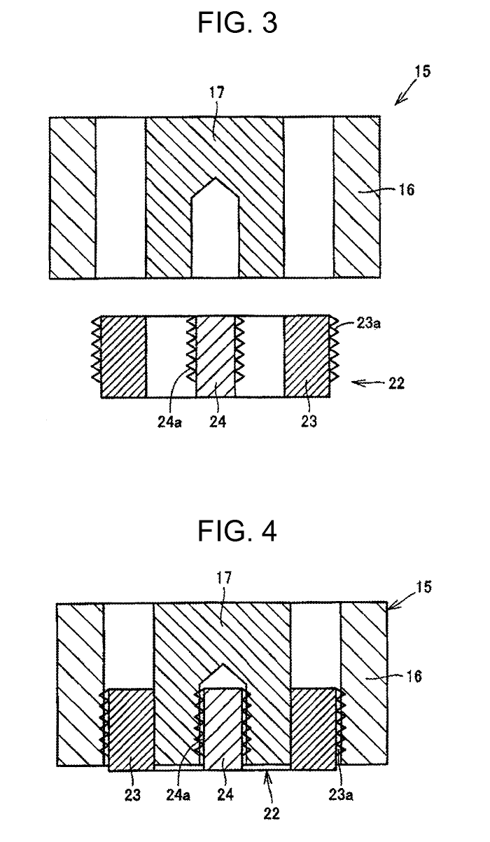

A plasma processing apparatus 11 according to an embodiment of the present invention will now be described with reference to FIGS. 1 through 4. FIG. 1 is a longitudinal cross-sectional view of the plasma processing apparatus 11, FIG. 2 is a plan view schematically illustrating the plasma processing apparatus 11, and FIGS. 3 and 4 are expanded views illustrating states where a lower electrode 14 and a matching box 21 are not connected and respectively connected to each other.

First, referring to FIG. 1, the plasma processing apparatus 11 according to the present embodiment includes a chamber 12, which is a process container having a process space S in which plasma processing is carried out, a matching box 21, and an air cylinder 31 as a fluid pressure cylinder.

The chamber 12 is a cylindrical process container that is formed using a conductor. In the chamber 12, an upper electrode 13 and the lower electrode 14 are arranged to face each other. Also, a gas supply source (not shown), which supplies a process gas, and an exhaust unit (not shown), which maintains the process space S at a predetermined pressure by exhausting the remaining process gas, are connected to the chamber 12. Also, the process gas includes a gas for carrying out plasma ignition, such as argon (Ar) gas, and a gas for wafer processing, such as CFx gas.

The upper electrode 13 is disposed to close an upper opening of the chamber 12 and is connected to a radio frequency (RF) power source (not shown) via the matching box 21. Also, a plurality of through holes 13a are formed in the upper electrode 13 by perpendicularly penetrating the upper electrode 13 and also act as a shower head that supplies the process gas into the process space S.

The lower electrode 14 faces the upper electrode 13 in a lower region of the chamber 12 and is connected to the RF power source (not shown) via the matching box 21. Also, the lower electrode 14 also acts as a susceptor that supports on a top surface thereof a semiconductor wafer W as a substrate to be processed. Also, an RF pipe 15 extends to the matching box 21 from a bottom surface of the lower electrode 14 so that the lower electrode 14 and the matching box 21 can be electrically connected to each other.

An operation of the plasma processing apparatus 11 having the above structure will now be described. First, the semiconductor wafer W is put on the top surface of the lower electrode 14, and the process space S is sealed. Next, as the process gas is supplied into the process space S from a process gas supply source (not shown) via the through holes 13a of the upper electrode 13, the process space S is maintained at a predetermined pressure by an exhaust unit (not shown).

Next, an RF voltage is applied to each of the upper electrode 13 and the lower electrode 14. For example, when a 60 MHz RF voltage is applied to the upper electrode 13 and a 2 MHz RF voltage is applied to the lower electrode 14, the gas for plasma ignition is ionized and plasmatized in the process space S, and a bias electric potential is generated between the upper electrode 13 and the lower electrode 14. Thus, the gas for wafer processing is activated, and plasma processing such as ion etching can be carried out on the surface of the semiconductor wafer W.

The matching box 21 is electrically connected to the upper electrode 13 and the lower electrode 14, respectively, and supplies an RF power from the RF power source (not shown) to the electrodes. Specifically, a connection terminal 22, which is disposed on the top surface of the matching box 21, and the RF pipe 15 are electrically connected to each other so that an RF power is supplied to the lower electrode 14. A description on a connection portion to the upper electrode 13 will be omitted herein.

The matching box 21 is moved to the lower portion of the chamber 12 along a rail 18 and is pulled up to a predetermined position by the air cylinder 31 so that the RF pipe 15 and the connection terminal 22 can be electrically connected to each other.

The air cylinder 31 is a double acting cylinder including: a cylinder case 32 including first and second cylinders 32a and 32b; a piston 33 separating the first and second cylinders 32a and 32b from each other and making a reciprocating motion in the cylinder case 32; a compressor (not shown) as a fluid supply unit supplying a fluid (“air” in the present embodiment) to the first and second cylinders 32a and 32b; a connection member 34 disposed outside the cylinder case 32 and connected to a member moved due to a fluid pressure (“matching box 21” in the present embodiment); and a connection rod 34a passing through the second cylinder 32b and connecting the piston 33 and the connection member 34. Also, the connection member 34 may be an electrostatic chuck, an electromagnet, or the like.

The air cylinder 31 fixes the cylinder case 32 at the bottom surface of the chamber 12 and the connection member 34 at the top surface of the matching box 21 with the first cylinder 32a placed above the piston 33. Also, the air cylinder 31 supplies compressed air to one of the first and second cylinders 32a and 32b so that the piston 33 can be moved upwards and downwards in a vertical direction.

In other words, when the compressed air is supplied to the second cylinder 32b, the piston 33 is pushed upwards. As a result, the matching box 21 connected to the piston 33 is pushed upwards so that the RF pipe 15 and the connection terminal 22 are connected to each other. Meanwhile, when the compressed air is supplied to the first cylinder 32a, the piston 33 is pushed downwards. As a result, the matching box 21 connected to the piston 33 is pushed downwards so that the RF pipe 15 and the connection terminal 22 are disconnected from each other.

Next, the relationship between a position of the chamber 12 and a position of the matching box 21 will be described with reference to FIG. 2. First, the RF pipe 15 extends downwards from the center of the chamber 12. Meanwhile, the air cylinder 31 is placed out of the center of the chamber 12 and is also disposed perpendicularly above the center of gravity G of the matching box 21.

In other words, since the connection member 34 is pulled up while being fixed perpendicularly above the center of gravity G of the matching box 21, the matching box 21 may be pulled up horizontally. As a result, the RF pipe 15 and the connection terminal 22 can be properly connected to each other.

The air cylinder 31 having the above structure has a small and simple structure as compared to the conventional elevation driving unit including a ball screw, etc. On the other hand, the air cylinder 31 generates a weak force for pulling up the matching box 21. However, as the portion where the RF pipe 15 and the connection terminal 22 are connected to each other is constituted below, the RF pipe 15 and the connection terminal 22 can be properly connected to each other.

Next, details of the portion where the RF pipe 15 and the connection terminal 22 are connected to each other will be described with reference to FIGS. 3 and 4. First, referring to FIG. 3, the RF pipe 15 includes a ground pipe 16 and an RF feeding rod 17 disposed inside the ground pipe 16. Meanwhile, the connection terminal 22 includes a terminal 23 for electric potential of the ground pipe 16 and an RF power terminal 24 disposed inside the terminal 23.

The ground pipe 16 is a female terminal that accommodates the terminal 23 for electric potential of the ground pipe 16 in a cylindrical inner diameter surface, and the terminal 23 for electric potential of the ground pipe 16 is a male terminal that is inserted in the inner diameter surface of the ground pipe 16. The ground pipe 16 and the terminal 23 for electric potential of the ground pipe 16 are connected to each other so that electric potential of the ground pipe 16 can be obtained simultaneously.

Similarly, the RF feeding rod 17 is a female terminal that accommodates the RF power terminal 24, and the RF power terminal 24 is a male terminal that is inserted in an inner diameter surface of the RF feeding rod 17. The RF feeding rod 17 and the RF power terminal 24 are connected to each other so that the lower electrode 14 can be connected to the RF power source (not shown).

Contact surfaces where the male terminals 23 and 24 contact the female terminals 16 and 17, that is, the outer diameter surface of the terminal 23 for electric potential of the ground pipe 16 and the outer diameter surface of the RF power terminal 24 are covered with elastic conductors 23a and 24a, respectively. The elastic conductor 23a is a cylindrical member formed of high-conductivity metal such as aluminum, copper, or the like. Also, the elastic conductor 23a has a wrinkled hose structure which is repeatedly bent forming a mountain portion and a valley portion alternately. An elastic deformation capability of the elastic conductor 23a in a diameter direction is high. In addition, the elastic conductor 24a has the same configuration as the elastic conductor 23a, and thus, description thereof will be omitted.

Since the outer diameter surfaces of the male terminals 23 and 24 are covered with the elastic conductors 23a and 24a, even though the outer diameter surfaces of the male terminals 23 and 24 and the inner diameter surfaces of the female terminals 16 and 17 do not directly contact each other, the male terminal 23 and the female terminal 16 and the male terminal 24 and the female terminal 17, respectively, can be electrically connected to each other. Specifically, the inner diameter of the ground pipe 16 may be set to be larger than the outer diameter of the terminal 23 for electric potential of the ground pipe 16 and smaller than the diameter of the mountain portion of the elastic conductor 23a. Similarly, the inner diameter of the RF feeding rod 17 may be set to be larger than the outer diameter of the RF power terminal 24 and smaller than the diameter of the mountain portion of the elastic conductor 24a.

When the male terminals 23 and 24 having the above configuration are inserted in the inner diameter surfaces of the female terminals 16 and 17, the elastic conductors 23a and 24a are elastically deformed so that the mountain portions thereof contact the inner diameter surfaces of the female terminals 16 and 17 and the valley portions thereof contact the outer diameter surfaces of the male terminals 23 and 24. Thus, even though a gap between the male terminals 23 and 24 and the female terminals 16 and 17 is formed to a degree, the male terminal 23 and the female terminal 16 and the male terminal 24 and the female terminal 17, respectively, can be electrically connected. In addition, in FIG. 4, the male terminal 23 and the female terminal 16 and the male terminal 24 and the female terminal 17, respectively, overlap with each other so as to make a portion where each of the female terminals 16 and 17 and each of the elastic conductors 23a and 24a firmly overlap with each other.

As a result of the above configuration, a resistance that occurs when the male terminal 23 and the female terminal 16 and the male terminal 24 and the female terminal 17, respectively, are connected to each other can be reduced, and the terminal 23 and the female terminal 16 and the male terminal 24 and the female terminal 17, respectively, can be prevented from being damaged when connected to each other. Also, due to a reduction in the resistance that occurs when the male terminal 23 and the female terminal 16 and the male terminal 24 and the female terminal 17, respectively, are connected to each other, the above-described, small-sized air cylinder 31 can be used as the elevation driving unit for the matching box 21.

Also, in the present embodiment, the elastic conductors 23a and 24a are adhered to the terminal 23 for electric potential of the ground pipe 16 and the RF power terminal 24, which are the male terminals. However, the present invention is not limited to this structure, and the inner diameter surfaces of the ground pipe 16 and the RF feeding rod 17, which are the female terminals, may be covered with the elastic conductors 23a and 24a, or the elastic conductors 23a and 24a may be adhered to both of the male terminals 23 and 24 and the female terminals 16 and 17.

Also, in the present embodiment, the elastic conductors 23a and 24a having the wrinkled hose structure have been described. However, the present invention is not limited to this structure, and any elastic conductor having a high elastic deformation capability may be used.

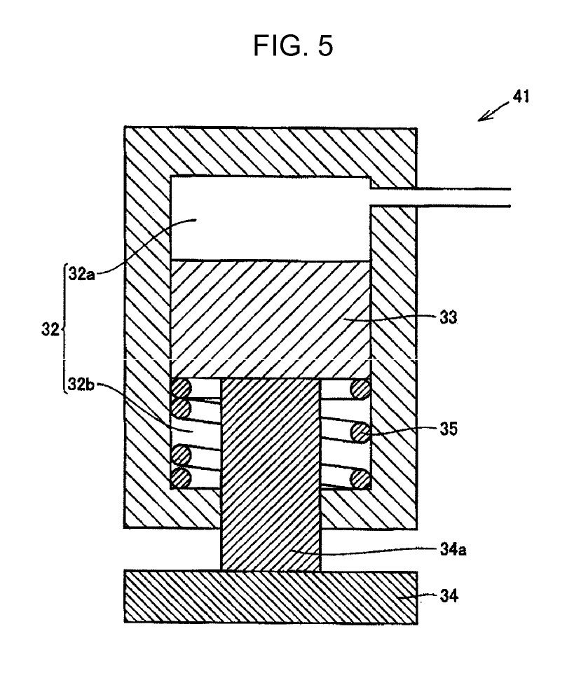

Next, an air cylinder 41 as a fluid pressure cylinder according to another embodiment of the present invention will be described with reference to FIG. 5. Also, the same elements as those of the air cylinder 32 of FIG. 1 are indicated by the same reference numerals, and detailed descriptions thereof will be omitted.

The air cylinder 41 is a single acting cylinder in which an elastic member 35 elastically supporting the piston 33 toward the first cylinder 32a (“coil spring” in the present embodiment) is disposed in the second cylinder 32b, instead of connecting the second cylinder 32b to the compressor. The air cylinder 41 is disposed at the bottom surface of the chamber 12 with the first cylinder 32a placed above the second cylinder 32b.

In the air cylinder 41 having the above configuration, in an initial state (“a state where the compressed air is not supplied to the first cylinder 32a”), the elastic member 35 pushes up the piston 33 in a vertical, upward direction. As a result, the matching box 21 connected to the piston 33 is pushed upwards so that the RF pipe 15 and the connection terminal 22 can be electrically connected to each other. Meanwhile, when the compressed air is supplied to the first cylinder 32a, the piston 33 is pushed downwards against the elastic member 35. As a result, the matching box 21 connected to the piston 33 is pushed downwards so that the RF pipe 15 and the connection terminal 22 can be disconnected from each other.

In the air cylinder 41 having the above configuration, the elastic member 35 always elastically supports the piston 33 towards the first cylinder 32a. Thus, even when the compressed air cannot be supplied to the first cylinder 32a due to breakdown of the compressor, the RF pipe 15 and the connection terminal 22 are not disconnected from each other. As such, the plasma processing apparatus 11 has high reliability.

In addition, in the present embodiment, the air cylinder 31 or 41 is used as a fluid pressure cylinder. However, the present invention is not limited to this structure, and any configuration capable of elevating the matching box 21 using a fluid pressure may be used. For example, a hydraulic cylinder using oil instead of air may be used.

As described above, in the plasma processing apparatus according to the present invention, an elastic conductor is disposed at a portion where a lower electrode and a matching box are connected to each other, and a fluid pressure cylinder is used as an elevation driving unit for the matching box such that the plasma processing apparatus can be miniaturized and the lower electrode and the matching box can be electrically connected to each other.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A plasma processing apparatus comprising:
an upper electrode and a lower electrode facing each other;
a process container in which a substrate supported by the lower electrode is plasma processed;
a matching box electrically connected to the lower electrode, wherein the matching box is freely attached and detached with respect to the lower electrode and supplies a radio frequency (RF) power to the lower electrode; and
a fluid pressure cylinder fixed at the process container and pulling up the matching box to a position where the matching box is connected to the lower electrode,
wherein the lower electrode and the matching box are electrically connected to each other via a female terminal connected to one of the lower electrode and the matching box and a male terminal connected to other one of the lower electrode and the matching box and inserted in the female terminal, and
wherein at least one of the female terminal and the male terminal comprises an elastic conductor covering a contact surface which contacts other one of the female terminal and the male terminal.

2. The plasma processing apparatus of claim 1, wherein the elastic conductor is a cylindrical member having a wrinkled hose structure.

3. The plasma processing apparatus of claim 1, wherein the fluid pressure cylinder is disposed perpendicularly above a center of gravity of the matching box.

4. The plasma processing apparatus of claim 1, wherein the fluid pressure cylinder is an air cylinder using air pressure.

5. The plasma processing apparatus of claim 1, wherein the fluid pressure cylinder is a double acting cylinder.
